(19) United States
(12) Patent Application Publication
(10) Pub. No.: US 2019/0228828 A1
(43) Pub. Date: Jul. 25, 2019

(54) SEMICONDUCTOR DEVICE

(71) Applicant: Sharp Kabushiki Kaisha, Sakai City, Osaka (JP)

(72) Inventor: Kaoru YAMAMOTO, Sakai City (JP)

(21) Appl. No.: 16/330,219

(22) PCT Filed: Aug. 28, 2017
(86) PCT No.: PCT/JP2017/030781

§ 371 Date: Mar. 4, 2019

(30) Foreign Application Priority Data
Sep. 5, 2016 (JP) 2016-173024

(51) Int. Cl. G11C 17/06; H01L 27/105; H01L 29/786; H01L 49/02

(52) U.S. Cl. CPC G11C 17/06; H01L 49/02; H01L 29/78603; H01L 27/1052

(57) ABSTRACT

Provided is a semiconductor device having a plurality of memory cells (MC1 and MC2), in which each of the plurality of memory cells (MC1 and MC2) includes: a memory transistor (10M) having an oxide semiconductor layer (17M) as an active layer; and a first selection transistor (10S) having a crystalline silicon layer (13S) as the active layer and connected to the memory transistor (10M) in series.

### TECHNICAL FIELD

The present invention relates to a semiconductor device including a memory transistor.

### BACKGROUND ART

In general, an element having a transistor structure (hereinafter, referred to as “memory transistor”) has been proposed as a memory element usable for a read only memory (ROM).

The present applicant has proposed a novel memory transistor capable of reducing power consumption as compared with the related art, a nonvolatile storage device including the memory transistor, and a liquid crystal display device, in PTLs 1 to 4. The novel memory transistor uses a metal oxide semiconductor (hereinafter, referred to as “oxide semiconductor”) as an active layer and may be irreversibly changed to a resistor state exhibiting an ohmic resistance performance regardless of the gate voltage by Joule heat generated by the drain current. For reference, the descriptions of PTLs 1 to 4 are incorporated herein by reference in their entireties.

As used herein, the operation of changing the oxide semiconductor of this memory transistor to the resistor state is referred to as “write”. In addition, this memory transistor does not operate as a transistor because the oxide semiconductor serves as a resistor after the write, although this memory transistor is still referred to as a “memory transistor” herein even after being changed to a resistor. Likewise, even after change to a resistor, the same designations of the elements forming a transistor structure, such as a gate electrode, a source electrode, a drain electrode, an active layer, and a channel region are used.

### CITATION LIST

### Patent Literature

PTL 1: International Publication No. 2013/080784 (U.S. Pat. No. 9,209,196)
PTL 2: International Publication No. 2014/061633 (U.S. Pat. No. 9,312,264)
PTL 3: International Publication No. 2015/072196
PTL 4: International Publication No. 2015/075985

### SUMMARY OF INVENTION

### Technical Problem

However, when a memory cell is configured with a memory transistor and a selection transistor connected to the memory transistor in series, the oxide semiconductor of the selection transistor deteriorates during writing in some cases. In order to prevent this, as described in PTL 2, a selection transistor for writing and a selection transistor for reading are used as selection transistors, but there still is a problem that it is necessary to fabricate a large transistor as a selection transistor for writing, which results in increased memory cell size.

The present invention has been made to solve the above problems, and an aspect of the present invention is to provide a semiconductor device including a memory transistor having an active layer formed of an oxide semiconductor, which can be highly integrated as compared with the related art.

### Solution to Problem

A semiconductor device according to an embodiment of the present invention is a semiconductor device including a plurality of memory cells, in which each of the plurality of memory cells includes a memory transistor having an oxide semiconductor layer as an active layer, and a first selection transistor having a crystalline silicon layer as the active layer and connected to the memory transistor in series. For example, the semiconductor device is a nonvolatile storage device in which a plurality of memory cells are arranged in a matrix.

According to the embodiment, each of the plurality of memory cells further includes a second selection transistor having a crystalline silicon layer as an active layer and connected to the memory transistor in series. The first selection transistor and the second selection transistor are connected in parallel.

According to the embodiment, the transistors that are included in each of the plurality of memory cells are only the memory transistor and the first selection transistor.

According to the embodiment, the semiconductor device is an active matrix substrate, the semiconductor device includes a display region including a plurality of pixel electrodes and pixel transistors each of which is electrically connected to the corresponding pixel electrode of the plurality of pixel electrodes, and a peripheral region having a plurality of circuits arranged in a region other than the display region, the plurality of circuits include a memory circuit having the plurality of memory cells, and an active layer of the pixel transistor includes a semiconductor layer formed of the same oxide semiconductor film as that of the oxide semiconductor layer of the memory transistor. The active matrix substrate is used for a liquid crystal display panel or an organic EL display panel, for example.

According to the embodiment, the oxide semiconductor layer includes an In—Ga—Zn—O-based semiconductor.

According to the embodiment, the oxide semiconductor layer includes a crystalline In—Ga—Zn—O-based semiconductor.

According to the embodiment, the active layer of the memory transistor has a stacked structure. The pixel transistor may also have a stacked structure.

According to the embodiment, the memory transistor is a channel etch type.

### Advantageous Effects of Invention

According to an embodiment of the present invention, it is possible to provide a semiconductor device, including a memory transistor having an active layer formed of an oxide semiconductor, which can be highly integrated as compared with the related art.

### BRIEF DESCRIPTION OF DRAWINGS

FIGS. 1(a) and 1(b) are diagrams schematically showing configurations of memory cells MC1 and MC2 included in a semiconductor device according to an embodiment of the present invention.

FIG. 2 is a schematic cross-sectional view of a memory transistor 10M and a selection transistor 10S.

FIGS. 3(a) and B are diagrams showing equivalent circuit of the memory cell MC2, in which FIG. 3(a) shows an example of writing, and FIG. 3(b) shows an example of reading.

FIG. 4 is a diagram schematically showing an example of voltage waveforms of voltages Vdp, Vgp, and Vsp applied to respective terminals of a memory transistor Qm, which is divided into four patterns.

FIG. 5(a) is a graph showing the voltage-current performances before and after writing of the oxide semiconductor TFT, and FIG. 5(b) is a graph showing voltage-current performances of a TFT having an In—Ga—Zn—O-based semiconductor layer, a TFT having a polycrystalline silicon (LIPS) layer, and a TFT having an amorphous silicon layer.

FIG. 6 is a circuit block diagram of a nonvolatile storage device 120 according to an embodiment of the present invention.

FIG. 7 is a schematic plan view of the entire active matrix substrate 100 according to an embodiment of the present invention.

FIG. 8 is a schematic cross-sectional view of an active matrix substrate 100.

### DESCRIPTION OF EMBODIMENTS

Hereinafter, a semiconductor device having a plurality of memory cells according to an embodiment of the present invention will be described with reference to the drawings.

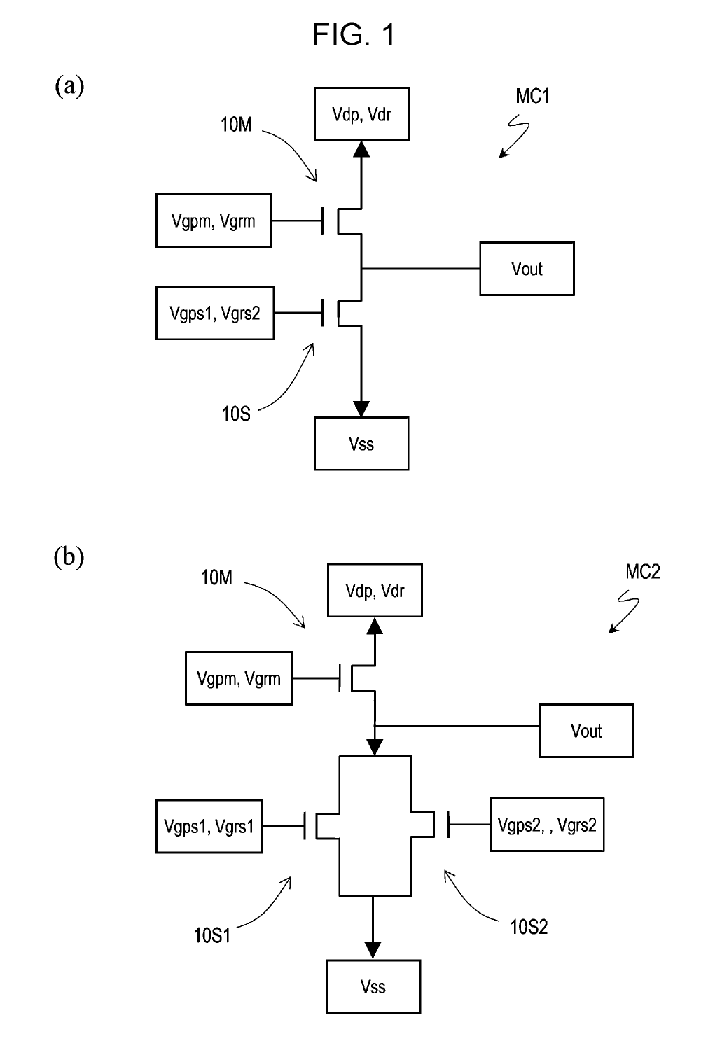

FIGS. 1(a) and 1(b) schematically show a configuration of a memory cell included in a semiconductor device according to an embodiment of the present invention.

A memory cell MC1 shown in FIG. 1(a) includes a memory transistor 10M having an oxide semiconductor layer as an active layer, and a selection transistor 10S having a crystalline silicon layer as an active layer and connected to the memory transistor 10M in series. The only transistors that are included in the memory cell MC1 are the memory transistor 10M and the selection transistor 10S.

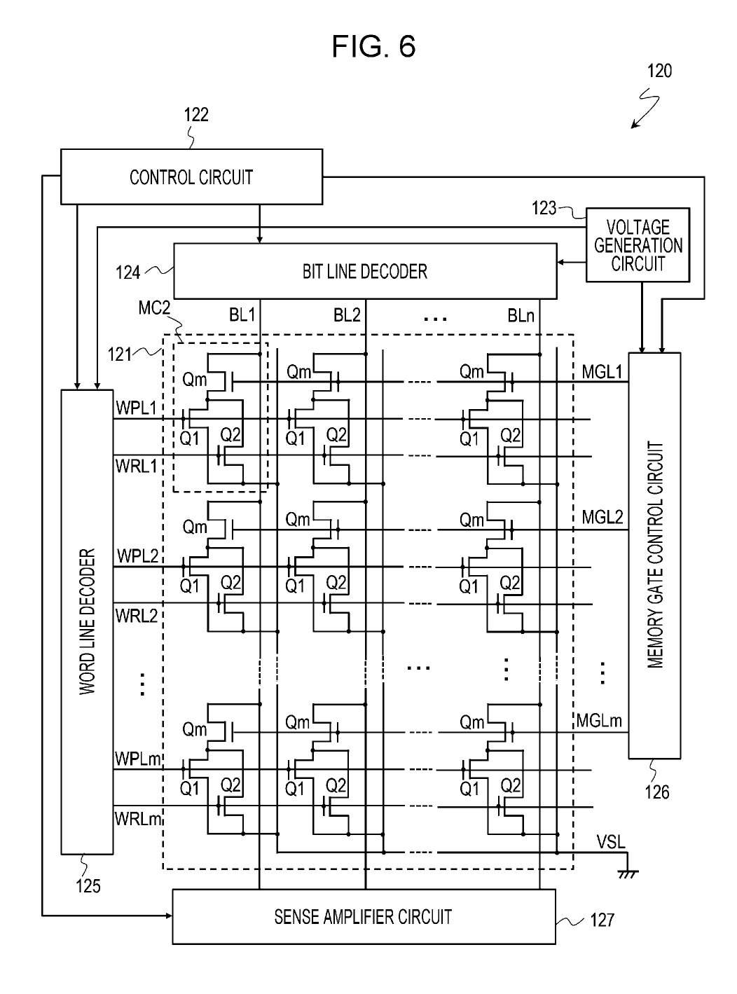

The memory cell MC2 shown in FIG. 1(b) further includes a memory transistor 10M having an oxide semiconductor layer as an active layer, a first selection transistor 10S1 having a crystalline silicon layer as an active layer and connected to the memory transistor 10M in series and a second selection transistor 10S2 having a crystalline silicon layer as an active layer and connected to the memory transistor 10M in series. The first selection transistor 10S1 and the second selection transistor 10S2 are connected in parallel. The first selection transistor 10S1 is a selection transistor for writing, for example, and the second selection transistor 10S2 is a selection transistor for reading, for example. A semiconductor device according to an embodiment of the present invention is a nonvolatile storage device in which a plurality of memory cells MC1 or a plurality of memory cells MC2 are arranged in a matrix, for example (see FIG. 6).

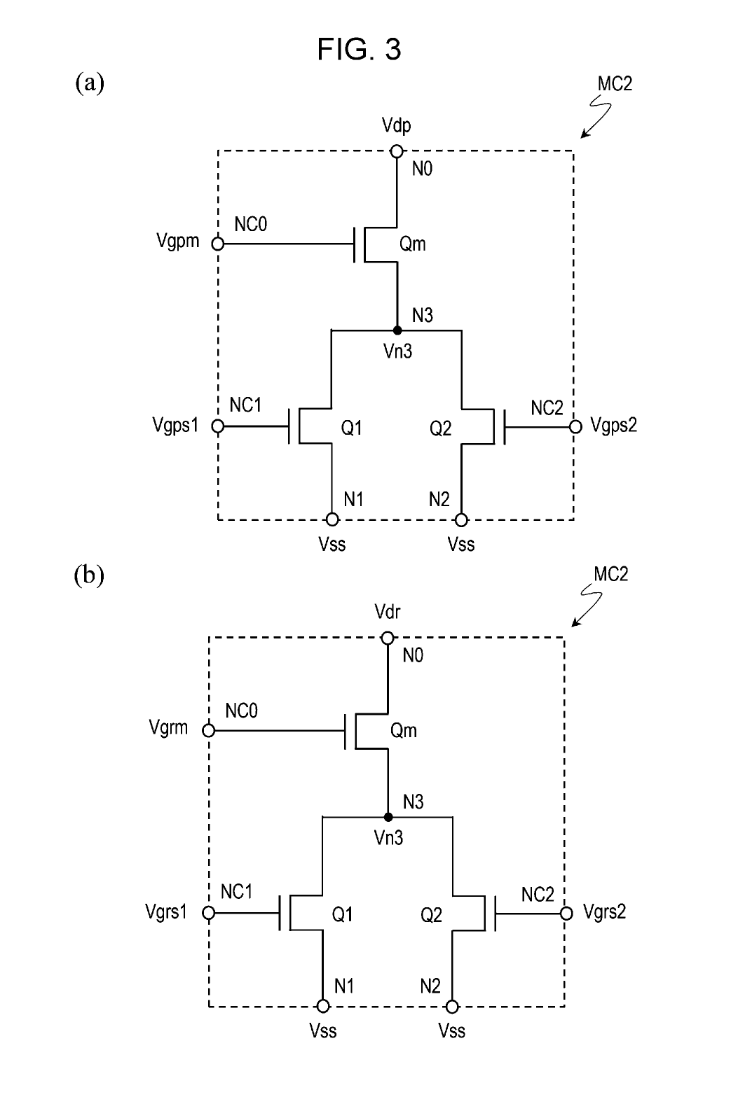

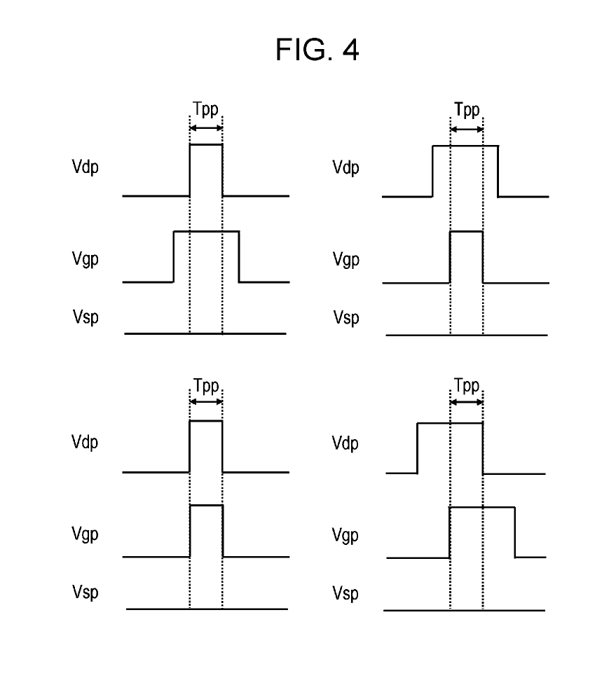

The respective voltages (Vdp, Vdr, Vss, Vgpm, Vgrm, Vgps1, Vgrs1, Vgps2, and Vgrs2) supplied to the memory cells MC1 and MC2 shown in FIG. 1 and the operation of the memory cells MC1 and MC2, will be described below with reference to FIGS. 3 and 4. Among the subscripts of the symbols indicating each voltage, “p” represents “during writing”, “r” represents “during reading”, and “m”, “s1”, and “s2” represent three transistors of the memory cell MC2. Since the selection transistor 10S of the memory cell MC1 serves as the first selection transistor 10S1 of the memory cell MC2 during writing and serves as the second selection transistor 10S2 of the memory cell MC2 during reading, the voltage supplied to a gate of the first selection transistor 10S1 is denoted by Vgps1 and Vgrs2.

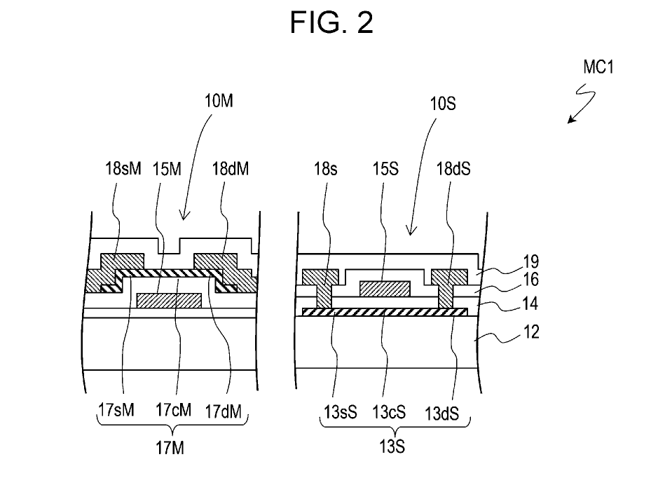

FIG. 2 is a schematic cross-sectional view of the memory transistor 10M and the selection transistor 10S. Here, the memory cell MC1 formed on the substrate 12 will be described. That is, the semiconductor device exemplified here includes a substrate 12, a memory transistor 10M formed on the substrate 12, and a selection transistor 10S. Each transistor is a thin film transistor (TFT). A TFT having an oxide semiconductor layer as an active layer is referred to as an oxide semiconductor TFT and a TFT having a crystalline silicon layer as an active layer is referred to as a crystalline silicon TFT, in some cases.

The substrate 12 is a glass substrate, for example, and a base film (not shown) may be formed on the substrate 12. When the base film is formed, circuit elements such as the selection transistor 10S and the memory transistor 10M are formed on the base film. Although the base film is not particularly limited, it is an inorganic insulating film, for example, a laminated film having a silicon nitride (SiNx) film, a silicon oxide (SiOx) film, or a silicon nitride film as a lower layer and a silicon oxide film as an upper layer.

The memory transistor 10M includes a gate electrode 15M, an oxide semiconductor layer 17M, a gate insulating film (second insulating film) 14 disposed between the gate electrode 15M and the oxide semiconductor layer 17M, and a source electrode 18sM and a drain electrode 18dM electrically connected to the oxide semiconductor layer 17M. When viewed from the normal direction of the substrate 12, at least a part of the oxide semiconductor layer 17M is disposed to overlap the gate electrode 15M through the gate insulating film (first insulating layer) 14 that is interposed therebetween. The source electrode 18sM may be in contact with a part of the oxide semiconductor layer 17M and the drain electrode 18dM may be in contact with another part of the oxide semiconductor layer 17M. The gate electrode 15M is disposed on the substrate 12 side of the oxide semiconductor layer 17M, and the memory transistor 10M is a bottom gate type TFT.

A region in contact with (or electrically connected to) the source electrode 18sM in the oxide semiconductor layer 17M is referred to as a “source contact region 17sM”, a region in contact with (or electrically connected to) the drain electrode 18dM is referred to as a “drain contact region 17dM”. When viewed from the normal direction of the substrate 12, a region of the oxide semiconductor layer 17M, which is overlapped with the gate electrode 15M through the gate insulating film 14 interposed therebetween and located between the source contact region 17sM and the drain contact region 17dM, is the channel region 17cM. When the source electrode 18sM and the drain electrode 18dM are in contact with an upper surface of the oxide semiconductor layer 17M, when viewed from the normal direction of the substrate 12, a region of the oxide semiconductor layer 17M, which is located between the source electrode 18sM and the drain electrode 18dM, is the channel region 17cM. When viewed from the normal direction of the substrate 12, the source electrode 18sM and the drain electrode 18dM have portions overlapping with both the gate electrode 15M and the oxide semiconductor layer 17M.

The oxide semiconductor included in the oxide semiconductor layer 17M may be an amorphous oxide semiconductor or a crystalline oxide semiconductor having a crystalline portion. Examples of the crystalline oxide semiconductor include a polycrystalline oxide semiconductor, a microcrystalline oxide semiconductor, a crystalline oxide semiconductor in which c-axis is oriented substantially perpendicular to the layer surface, and the like.

The oxide semiconductor layer 17M may have a stacked structure of two or more layers. When the oxide semiconductor layer 17M has a stacked structure, the oxide semiconductor layer 17M may include an amorphous oxide semiconductor layer and a crystalline oxide semiconductor layer. Alternatively, a plurality of crystalline oxide semiconductor layers having different crystal structures may be included. In addition, a plurality of amorphous oxide semiconductor layers may be included. When the oxide semiconductor layer 17M has a two-layer structure including an upper layer and a lower layer, the energy gap of the oxide semiconductor included in the upper layer is preferably larger than the energy gap of the oxide semiconductor included in the lower layer. However, when the difference in energy gap between these layers is relatively small, the energy gap of the oxide semiconductor in the lower layer may be larger than the energy gap of the oxide semiconductor in the upper layer.

A material, a structure, a film formation method, a structure of an oxide semiconductor layer having a stacked structure, and the like of the amorphous oxide semiconductor and each of the crystalline oxide semiconductors described above are described in Japanese Unexamined Patent Application Publication No. 2014-007399, for example. For reference, the description of Japanese Unexamined Patent Application Publication No. 2014-007399 is incorporated herein in its entirety by reference.

The oxide semiconductor layer 17M may include at least one metal element selected from In, Ga, and Zn, for example. In this embodiment, the oxide semiconductor layer 17M includes an In—Ga—Zn—O-based semiconductor (for example, indium gallium zinc oxide), for example. Here, the In—Ga—Zn—O-based semiconductor is a ternary oxide of In (indium), Ga (gallium), Zn (zinc), and the ratio of In, Ga and Zn (composition ratio) is not particularly limited, but includes In:Ga:Zn=2:2:1, In:Ga:Zn=1:1:1, In:Ga:Zn=1:1:2, for example. Such an oxide semiconductor layer 17M may be formed of an oxide semiconductor film including an In—Ga—Zn—O-based semiconductor.

The In—Ga—Zn—O-based semiconductor may be amorphous or crystalline. As a crystalline In—Ga—Zn—O-based semiconductor, a crystalline In—Ga—Zn—O-based semiconductor in which the c-axis is oriented substantially perpendicular to the layer surface is preferable.

The crystal structure of a crystalline In—Ga—Zn—O-based semiconductor is disclosed in Japanese Unexamined Patent Application Publication No. 2014-007399, Japanese Unexamined Patent Application Publication No. 2012-134475 and Japanese Unexamined Patent Application Publication No. 2014-209727 described above, for example. For the sake of reference, the descriptions of Japanese Unexamined Patent Application Publication No. 2012-134475 and Japanese Unexamined Patent Application Publication No. 2014-209727 are incorporated herein in its entirety by reference.

The oxide semiconductor layer 17M may include other oxide semiconductor instead of In—Ga—Zn—O-based semiconductor. For example, it may include In—Sn—Zn—O-based semiconductor (for example, In₂O₃—SnO₂—ZnO; InSnZnO). The In—Sn—Zn—O-based semiconductor is a ternary oxide of In (indium), Sn (tin) and Zn (zinc). Alternatively, the oxide semiconductor layer 17M may be formed of an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, a CdO (cadmium oxide), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, and the like.

The drain electrode 18dM is preferably formed of a metal having a melting point of 1200° C. or higher, and more preferably, formed of a metal having a melting point of 1600° C. or higher, for example. Examples of such metals may include Ti (titanium, melting point: 1667° C.), Mo (molybdenum, melting point: 2623° C.), Cr (chromium, melting point: 1857° C.), W (tungsten, melting point: 3380° C.), Ta (tantalum, melting point: 2996° C.), or an alloy thereof. A metal layer having a melting point lower than 1200° C. may be laminated on the metal layer having a melting point of 1200° C. or higher. For example, Al (aluminum, melting point: 660° C.), Cu (copper, melting point: 1083° C.), or the like may be used. A metal nitride layer, a metal silicide layer or the like mainly including the metal described above may be used instead of the metal layer described above. The source electrode 18sM may be formed of a conductive film common to the drain electrode 18dM. A memory transistor of which electrode has such a stacked structure is described in PTL 3.

The memory transistor 10M is a nonvolatile memory element which can be irreversibly changed from a state (referred to as “semiconductor state”) in which the drain current Ids is dependent on the gate voltage Vgs to a state (referred to as “resistor state”) in which the drain current Ids is not dependent on the gate voltage Vgs. The drain current Ids is a current flowing between the source electrode 18sM and the drain electrode 18dM of the memory transistor 10M (between the source and the drain), and the gate voltage Vgs is a voltage between the gate electrode 15M and the source electrode 18sM (between the gate and the source).

The state change occurs by applying a predetermined write voltage Vds between the source and drain of the memory transistor 10M in the semiconductor state (initial state) and applying a predetermined gate voltage between the gate and the source, for example. By applying the write voltage Vds, a current (write current) flows in a portion (channel region) 17cM where a channel is formed in the oxide semiconductor layer 17M, so that Joule heat is generated. By this Joule heat, the resistance of the channel region 17cM in the oxide semiconductor layer 17M is lowered. As a result, the resistor state shows an ohmic resistance performance without depending on the gate voltage Vgs. The reason for the lowered resistance of the oxide semiconductor is still being elucidated, but it is considered that oxygen included in the oxide semiconductor spreads out of the channel region 17cM by Joule heat, causing increasing oxygen deficiency in the channel region 17cM and generation of the carrier electrons. Memory transistors that can cause such state changes are described in PTLs 1 to 4.

In the case of an n-channel type memory transistor exemplified here, an upstream side in the direction in which the drain current Ids flows is the drain, and a downstream side therein is the source. As used herein, the “source electrode” indicates an electrode electrically connected to the source side of the active layer (in this case, the oxide semiconductor layer 17M) and may be a part of the wiring (source wiring). Typically, the “source electrode” includes not only a contact portion directly contacting the source side of the active layer, but also a portion located in the vicinity thereof. For example, when a part of the source wiring is electrically connected to the active layer, the “source electrode” includes a portion of the source wiring located in the memory transistor forming region. Alternatively, the “source electrode” may include a portion of the source wiring spanning from a contact portion in contact with the active layer to a portion connected to another element or another wiring. Likewise, the “drain electrode” indicates an electrode electrically connected to the drain side of the active layer (in this case, the oxide semiconductor layer 17M), and may be a part of the wiring. The “drain electrode” includes not only a contact portion directly contacting the drain side of the active layer, but also a portion located in the vicinity thereof. When a part of the wiring is electrically connected to the drain side of the active layer, the “drain electrode” includes a portion of its wiring which is located within the memory transistor forming region. For example, it may include a portion spanning from a contact portion in contact with the active layer to a portion connected to another element or another wiring.

The selection transistor 10S includes a crystalline silicon layer (for example, a low temperature polysilicon layer) 13 formed on the substrate 12, a first insulating layer 14 covering the crystalline silicon layer 13S, and a gate electrode 15S provided on the first insulating layer 14. As shown in the drawing, the first insulating layer 14 extends to the region where the memory transistor 10M is formed, and the gate electrode 15M of the memory transistor 10M is formed of the same conductive film as the gate electrode 15S of the selection transistor 10S on the first insulating layer 14.

A portion of the first insulating layer 14, which is located between the crystalline silicon layer 13S and the gate electrode 15S, serves as a gate insulating film of the selection transistor 10S. The crystalline silicon layer 13S includes a region (active region) 13cS where a channel is formed and a source region 13sS and a drain region 13dS located on both sides of the active region, respectively. In this example, the portion of the crystalline silicon layer 13S, which is overlapping with the gate electrode 15S through the first insulating layer 14 interposed therebetween, is an active region 13cS. The selection transistor 10S also includes a source electrode 18sS and a drain electrode 18dS connected to the source region 13sS and the drain region 13dS, respectively. The source electrode 18sS and the drain electrode 18dS may be provided on an interlayer insulating film (here, the second insulating layer 16) covering the gate electrode 15S and the crystalline silicon layer 13S, and may be formed within a contact hole formed on the interlayer insulating film to be connected to the crystalline silicon layer 13S. As described above, the selection transistor 10S is a top gate type TFT. The selection transistors 10S1 and 10S2 included in the memory cell MC2 in FIG. 1(b) have the same structure as the selection transistor 10S, respectively.

Here, “crystalline silicon” includes polycrystalline silicon as well as at least partially crystallized silicon such as microcrystalline silicon (μC-Si). The polycrystalline silicon is a low temperature polysilicon (LTPS), for example. As is well known, the low temperature polysilicon is formed by irradiating amorphous silicon deposited on a substrate with laser light to melt and crystallize the same (laser annealing).

In the memory cell MC1 included in the semiconductor device according to an embodiment of the present invention, a crystalline silicon TFT is used as the selection transistor 10S. In the MC2 included in the semiconductor device according to an embodiment of the present invention, a crystalline silicon TFT is used as at least the selection transistor for writing (for example, the selection transistor 10S1) among the two selection transistors 10S1 and 10S2.

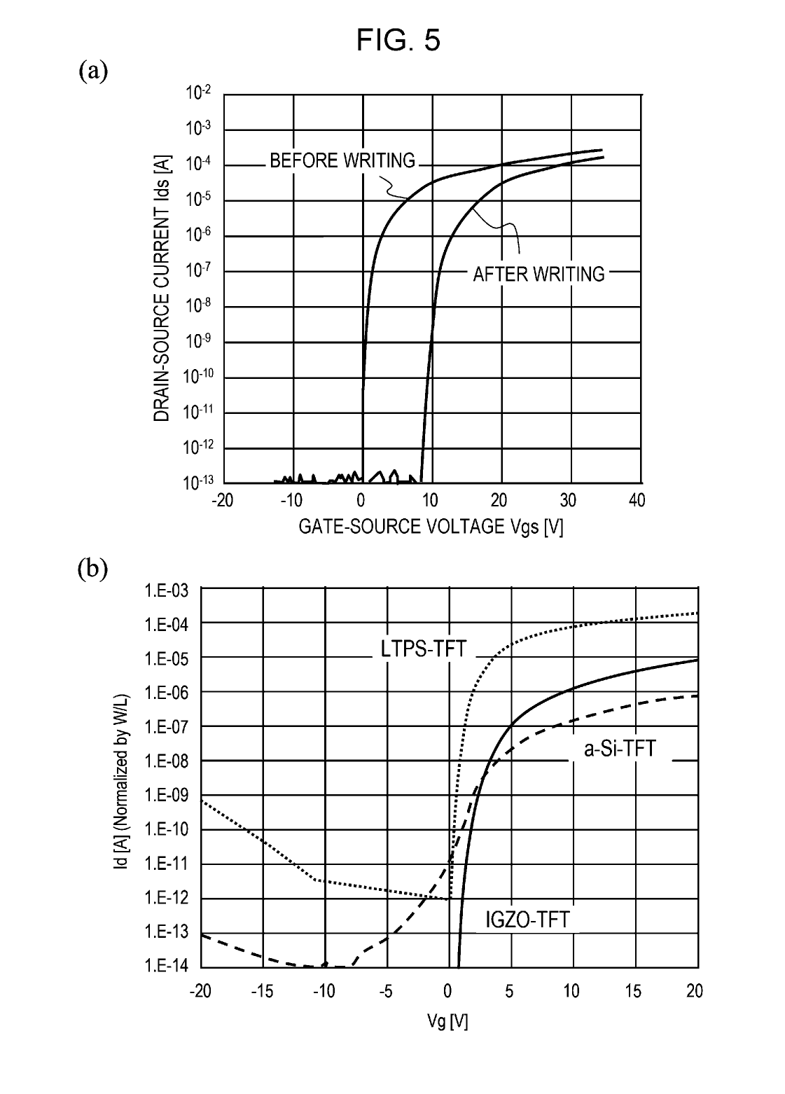

The current driving capability of the crystalline silicon TFT (magnitude of on-current) is about 20 times greater than the current driving capability of the oxide semiconductor TFT (see FIG. 5(b) for example). Therefore, during writing, the semiconductor (in related art, oxide semiconductor) forming the active layer of the selection transistor is not deteriorated. Further, when the selection transistor for writing and the selection transistor for reading are used, it is not necessary to increase the size of the selection transistor for writing.

Hereinafter, the operation of the memory cell MC2 included in the semiconductor device according to an embodiment of the present invention will be described with reference to FIGS. 3 and 4. Since it is explained in detail in PTL 2, an example of a typical operation will be described here.

FIGS. 3(a) and 3(b) are equivalent circuit diagrams of the memory cell MC2, in which FIG. 3(a) shows an example of writing, and FIG. 3(b) shows an example of reading. A transistor Qm corresponds to the memory transistor 10M, and transistors Q1 and Q2 correspond to the selection transistors 10S1 and 10S2, respectively.

As shown in FIG. 3, the memory cell MC2 includes a memory transistor Qm, a first selection transistor Q1 and a second selection transistor Q2. The first selection transistor Q1 and the second selection transistor Q2 are connected in parallel. The transistors Qm, Q1 and Q2 are all n channel type transistors (TFTs). The memory cell MC2 includes three nodes N0, N1, and N2, three control nodes NC0, NC1 and NC2, and one internal node N3. The source of the memory transistor Qm and the drains of the first selection transistor Q1 and the second selection transistor Q2 are mutually connected to form an internal node N3. The drain of the memory transistor Qm forms the node N0, the source of the first selection transistor Q1 forms the node N1, and the source of the second selection transistor Q2 forms the node N2, respectively. In addition, the gates of the transistors Qm, Q1 and Q2 sequentially form the control nodes NC0, NC1, and NC2.

The first selection transistor Q1 is a selection transistor that selects the memory cell MC2 subjected to the write operation, and is in ON state during writing and OFF state during reading. On the other hand, the second selection transistor Q2 is a selection transistor that selects the memory cell MC2 subjected to the read operation, and is in ON state during reading and OFF state during writing.

In the initial state after its manufacture, the transistor Qm shows a semiconductor state in which the transistor operation can be performed according to the voltage application state of the source electrode, the drain electrode, and the gate electrode, but when Joule heat is generated in the channel region by a current having a current density equal to or greater than a predetermined value flowing between the source electrode and the drain electrode, it exhibits an ohmic conductive performance (resistance performance) as a conductor, and is changed to a resistor state in which current controllability as a transistor is lost.

Here, the operation of transitioning the state of the memory transistor Qm from the semiconductor state to the resistor state is referred to as a write operation, and the operation of determining as to whether the state of the memory transistor Qm is the semiconductor state or the resistor state is referred to as a read operation.

In the following description, the ON state and the OFF state of the transistor Qm in the semiconductor state are controlled by the voltage between the gate and the source, and the ON state means a conduction state between the drain and the source (state in which a current corresponding to the applied voltage flows), and the OFF state means a non-conductive state between the drain and the source (state in which no current corresponding to the applied voltage flows), respectively. Even in the ON state, no current flows unless a voltage is applied between the drain and the source. Even in the OFF state, it is permitted that a minute current smaller by several orders of magnitude than the current flowing in the ON state flows between the drain and the source.

Next, the write operation to the single memory transistor Qm will be described. In the following description, it is assumed that, during writing, the voltage applied to the source (internal node N3) of the memory transistor Qm is Vsp, the voltage applied to the drain (node NO) of the memory transistor Qm is Vdp, the voltage applied to the gate (control node NC0) of the memory transistor Qm is Vgdp, while describing an example in which the predetermined reference voltage Vss is applied as the voltage Vsp applied to the source of Qm.

FIG. 4 schematically shows an example of voltage waveforms of voltages Vdp, Vgp, and Vsp applied to each terminal of the memory transistor Qm, which is divided into four patterns. An overlapping period between an application period of the write drain voltage Vdp and an application period of the write gate voltage Vgp is a write period Tpp.

Whichever of the above four patterns, voltage Vdsp (=Vdp−Vsp) is applied between the drain and the source of the memory transistor Qm, voltage Vgsp (=Vgp−Vsp) is applied between the gate and the source of the memory transistor Qm, the memory transistor Qm in the semiconductor state is in ON state, and in the write period Tpp, the write current Idsp flows between the drain and the source.

When the write current Idsp flows between the drain and the source of the memory transistor Qm, the write power Pw (=Vdsp×Idsp) expressed by the product of voltage Vdsp (=Vdp−Vsp) between the drain and source is consumed in the channel region 17cM of the oxide semiconductor layer 17M, and Joule heat corresponding to the write power Pw is generated, heating the channel region 17cM. As a result, the composition change of the channel region 17cM is induced, and the memory transistor Qm changes from the semiconductor state to the resistor state.

The write power Pw is set so that the temperature of the channel region 17cM is 200° C. or higher and 900° C. or lower, for example. When it is in a range from 200° C. to 900° C., the channel region 17cM is not fused by the Joule heat, and there is no disconnection by the electromigration of elements forming the oxide semiconductor layer 17M, and as a result, the chemical composition ratio of the oxide semiconductor layer 17M is changed. The write current Idsp is set according to the current density flowing in the channel region so that the current density per channel width W is in the range of 20 to 1000 μA/μm, for example. In addition, the writing period Tpp is set to satisfy the conditions described above in the range of 10 μsec to 500 msec, for example.

Furthermore, the write voltage Vdsp is applied in a state where the substrate temperature is raised in advance, so that it is possible to reduce the power required for the temperature rise, to increase the speed of reaching the temperature required for writing, and to perform the writing at a higher speed. In addition, it is possible to perform the writing with a write voltage of a low voltage.

Next, the read operation for a single memory transistor Qm will be described. In the following description, a predetermined reference voltage Vsr is applied to the source of Qm, as applying voltage Vsp, a predetermined read drain voltage Vdr is applied to the drain (node N0) of the memory transistor Qm, and a predetermined read gate voltage Vgr is applied to the gate (control node NC0) of the memory transistor Qm. As a result, voltage Vdsr (=Vdr−Vsr) is applied between the drain and the source of the memory transistor Qm, and voltage Vgsr (=Vgr−Vsr) is applied between the gate and the source of the memory transistor Qm. Here, the voltage Vgsr (=Vgr−Vsr) is set to be lower than a threshold voltage Vthm when the memory transistor Qm is in the semiconductor state before the write operation. As a result, when the memory transistor Qm is in the semiconductor state, the memory transistor Qm is in the OFF state, and even when the voltage Vdsr (=Vdr−Vsr) is applied between the drain and the source, the read current Idsr does not flow at all, or flows in a very small amount if any. On the other hand, when the memory transistor Qm is resistor state, since the current-voltage performance between the drain and the source of the memory transistor Qm exhibits an ohmic resistance performance irrespective of the read gate voltage Vgr, a read current Idsr corresponding to the voltage Vdsr (=Vdr−Vsr) and the resistance performance flows between the drain and the source. Therefore, by detecting the presence or absence, or the magnitude of the read current Idsr flowing between the drain and the source of the memory transistor Qm, it is possible to easily determine whether the memory transistor Qm is in the semiconductor state or the resistor state.

For example, logic values “0” and “1” are respectively assigned to the semiconductor state and the resistor state by performing the write operation and the read operation with respect to the memory transistor Qm, the memory transistor Qm may be used as a memory element that stores binary information in a nonvolatile manner.

FIG. 3(a) shows a first voltage application state to the memory cell MC2 during writing. The first voltage application state indicates a state in which the write drain voltage Vdp is applied to the drain of the memory transistor Qm (node N0), the write gate voltage Vgpm is applied to the gate of the memory transistor Qm (control node NC0), the reference voltage Vss is applied to the sources of the first and second selection transistors Q1 and Q2 (nodes N1 and N2), the write gate voltage Vgps1 is applied to the gate of the first selection transistor (control node NC1), the read gate voltage Vgps2 is applied to the gate of the second selection transistor (control node NC2), and the source of the memory transistor Qm (internal node N3) is at the voltage Vn3. Here, Vdp>Vn3>0 V, Vgpm>Vn3+Vthm, Vgps1>Vth1 and Vgps2<Vth2, where the reference voltage Vss is the ground voltage (0 V). Here, Vthm is the threshold voltage of the memory transistor, Vth1 is the threshold voltage of the first selection transistor Q1, and Vth2 is the threshold voltage of the second selection transistor Q2.

Since the read gate voltage Vgps2 lower than the threshold voltage Vth2 is applied to the gate of the second selection transistor Q2 (control node NC2) during writing to the memory cell MC2, the second selection transistor Q2 is controlled in the OFF state. For example, when Vth2>0 V, Vgps2=Vss (0 V). As a result, since no current flows between the drain and the source of the second selection transistor Q2 during the write operation, the deterioration of the transistor performance due to the current is prevented and the influence of the performance deterioration on the read operation may be prevented in advance.

Since the deterioration of the transistor performances described above may be avoided by preventing a current from flowing between the drain and the source of the second selection transistor Q2, even when the second selection transistor Q2 is in an ON state, for example, it is possible to prevent a current from flowing between the drain and the source by setting the second selection transistor Q2 to a floating state without applying the reference voltage Vss (ground voltage) to the source of the second selection transistor Q2 (node N2), thereby obtaining the same effect. Further, by controlling the second selection transistor Q2 in the OFF state during writing, the node N2 may be brought into optional voltage application state, for example, may be set to the same potential as that of the node N1, and furthermore, the nodes N1 and N2 may be short-circuited to form one node. Furthermore, when a memory cell array is configured using a plurality of memory cells MC2, even when a circuit configuration in which the nodes N2 are connected to a common signal line is adopted, the second selection transistor Q2 is controlled in the OFF state during writing, and as a result, a region between the internal nodes N3 of the selection memory cell which is the target of the write operation and the non-selection memory cell which is not the target of the write operation is non-conductive due to the second selection transistors Q2 being in the OFF state, so that the memory transistor Qm of the non-selection memory cell may be prevented from being erroneously written.

FIG. 3(b) shows the second voltage application state to the memory cell MC2 during reading. The second voltage application state indicates a state in which the read drain voltage Vdr is applied to the drain of the memory transistor Qm (node N0), the read gate voltage Vgrm is applied to the gate of the memory transistor Qm (control node NC0), the reference voltage Vss is applied to the sources of the first and second selection transistors Q1 and Q2 (nodes N1 and N2), the read gate voltage Vgrs1 is applied to the gate of the first selection transistor (control node NC1), the read gate voltage Vgrs2 is applied to the gate of the second selection transistor (control node NC2), and the source of the memory transistor Qm (internal node N3) is at the voltage Vn3. Here, Vdr>Vn3 0 V, Vgrm<Vn3+Vthm, Vgrs1<Vth1, Vgrs2>Vth2, where the reference voltage Vss is the ground voltage (0 V).

In the second voltage application state, likewise the read operation to a single memory transistor Qm, when the memory transistor Qm is in the semiconductor state, the memory transistor Qm is in the OFF state, and when the memory transistor Qm is in the resistor state, the current-voltage performance between the drain and the source of the memory transistor Qm exhibits an ohmic resistance performance irrespective of the read gate voltage Vgrm. As described above, the first selection transistor Q1 is in the OFF state and the second selection transistor is in the ON state. ON/OFF of the first and second selection transistors are reverse to those during writing.

As a result, when the memory transistor Qm is in the OFF state which is the semiconductor state, the voltage Vn3 of the internal node N3 of the memory cell MC2 is the reference voltage Vss by the second selection transistor Q2 which is in the ON state, and the read current Idsr does not flow between the node N0 and the node N2. On the other hand, when the memory transistor Qm exhibits a resistance performance in the resistor state, when the resistance value of the resistor state is Rm, the read current Idsr given by Idsr=(Vdr−Vn3)/Rm flows through the memory transistor Qm. In addition, current same as the read current Idsr flows between the drain and the source of the second selection transistor Q2.

As described above, when the memory transistor Qm is in the OFF state which is the semiconductor state, the read current Idsr does not flow and the voltage Vn3 of the internal node N3 is the reference voltage Vss, and when the memory transistor Qm exhibits the resistance performance in the resistor state, the read current Idsr flows and the voltage Vn3 of the internal node N3 is the voltage obtained by subtracting the voltage drop (Idsr×Rm) at the memory transistor Qm from the read drain voltage Vdr. Therefore, for example, by measuring the current value of the read current Idsr at the node N0 or by measuring the voltage at the internal node N3, it is possible to determine whether the memory transistor Qm is in the semiconductor state or in the resistor state. FIGS. 1(a) and 1(b) show an example of measuring the voltage of the internal node N3 (Vout).

As in the related art, when an oxide semiconductor TFT is used for the first selection transistor (selection transistor for writing) Q1, the write current Idsp flows through the first selection transistor Q1 during writing to the memory transistor Qm, and the deterioration phenomenon of the self-heating of the oxide semiconductor which may result in increase in the threshold voltage of the oxide semiconductor TFT and subsequent decrease in the ON current in some cases. For example, as shown in FIG. 5(a), the threshold voltage is shifted by approximately 10 V by writing. In order to guarantee the write performance, it is necessary that the write current is not lowered (current limit) until the writing is completed.

For example, when the current required for writing the TFT having the performances shown in FIG. 5(a) is 100 μA, a current of 100 μA or more may be obtained at Vgs=20 V before writing, whereas after writing, only a current of about 20 μA may be obtained at Vgs=20 V. In order to enable that a current of 100 μA or more is obtained until the writing is completed, it is necessary to increase the current capability after writing (after deterioration) 5 times or more, and accordingly, there is a need to increase the channel width W of the TFT 5 times or more. Accordingly, it is preferable that the magnitude of the channel width W of the first selection transistor Q1 is at least five times the channel width W of the memory transistor Qm.

In the semiconductor device according to an embodiment of the present invention, a crystalline silicon TFT (for example, polycrystalline silicon TFT) is used for at least the first selection transistor Q1 for writing. As can be seen from the graph shown in FIG. 5(b), the polycrystalline silicon TFT has a current driving capability (magnitude of Id) of about 20 times or more than that of the oxide semiconductor TFT. Therefore, even when the channel width W of the first selection transistor Q1 is set to be substantially equal to the channel width W of the memory transistor Qm, a sufficient current driving capability may be obtained. In addition, the crystalline silicon TFT is not deteriorated due to the current flowing in the channel region.

When the crystalline silicon TFT is used as a selection transistor, unlike the memory cell MC2, there is no need to provide two selection transistors for writing and reading, and like the memory cell MC1 shown in FIG. 1(a), one selection transistor 10S may be used as a selection transistor for writing and as a selection transistor for reading as well.

A semiconductor device according to an embodiment of the present invention is a nonvolatile storage device in which a plurality of the above memory cells are arranged in a matrix, for example.

FIG. 6 is a circuit block diagram of a nonvolatile storage device 120 according to an embodiment of the present invention.

The nonvolatile storage device 120 includes a memory cell array 121, a control circuit 122, a voltage generation circuit 123, a bit line decoder 124, a word line decoder 125, a memory gate control circuit 126, and a sense amplifier circuit 127.

The memory cell array 121 has a plurality of memory cells MC2 arranged in a matrix. The memory cell array 121 includes m memory cells MC2 arranged in a column direction and n memory cells MC2 arranged in a row direction, and further includes m memory gate lines MGL1 to MGLm (extending in the first control line) extending in the row direction, m first word lines WPL1 to WPLm (corresponding to the second control line) extending in the row direction, m second word lines WRL1 to WRLm (corresponding to the third control line) extending in the row direction, n bit lines BL1 to BLn (corresponding to data signal lines) extending in the column direction, and a reference voltage line VSL. Each of m and n is an integer of 2 or more.

Memory gate lines MGL1 to MGLm are connected in common to respective gates (control node NC0) of memory transistors Qm of n memory cells MC2 arranged in corresponding rows. Each of the first word lines WPL1 to WPLm is connected in common to each gate (control node NC1) of the first selection transistor Q1 of the n memory cells MC2 arranged in the corresponding row. Each of the second word lines WRL1 to WRLm is connected in common to each gate (control node NC2) of the second selection transistors Q2 of the n memory cells MC2 arranged in the corresponding row. Each of the bit lines BL1 to BLn is connected in common to each drain (node N0) of the memory transistors Qm of the m memory cells MC2 arranged in the corresponding column. The reference voltage line VSL is connected in common to the sources (nodes N1 and N2) of the first and second selection transistors Q1 and Q2 of all the memory cells MC2. In the present embodiment, the reference voltage Vss (for example, the ground voltage (0 V)) is constantly supplied to the reference voltage line VSL through the write operation and the read operation.

The memory cell array 121 may be read in the first voltage application state and written in the second voltage application state. That is, in the first and second voltage application states, the write drain voltage Vdp or the read drain voltage Vdr is applied to the bit line BL (representative name of the bit lines BL 1 to BLn) connected to the drain of the memory transistor Qm (node N0) of the memory cell MC 2 that is subjected to each operation, so that writing or reading may be performed.

The control circuit 122 controls the write operation and the read operation of the memory cell MC2 in the memory cell array 121. More specifically, the control circuit 122 controls the voltage generation circuit 123, the bit line decoder 124, the word line decoder 125, the memory gate control circuit 126, and the sense amplifier circuit 127 based on an address signal input from an address line (not shown), data input from a data line, and a control input signal input from a control signal line.

The voltage generation circuit 123 generates a selection gate voltage necessary for selecting the memory cell MC2 to be operated and a non-selection gate voltage to be applied to the non-selection memory cell MC2 not to be operated in the write operation and the read operation to supply the generated voltage to the word line decoder 125 and the memory gate control circuit 26. In addition, a bit line voltage necessary for writing and reading of the memory cell MC2 selected to be subjected to the operation is generated and supplied to the bit line decoder 124.

The selection gate voltages correspond to the gate voltages Vgpm, Vgps1, and Vgps2 during writing described above with reference to FIG. 3(a) and the gate voltages Vgrm, Vgrs1, and Vgrs2 during reading described above with reference to FIG. 3(b). The bit line voltage corresponds to the write drain voltage Vdp during writing and the read drain voltage Vdr during reading described in the first embodiment.

The non-selection gate voltages applied to the respective control nodes NC0 to NC2 during writing may be used as they are, as the selection gate voltages Vgrm, Vgrs1, and Vgrs2 applied to the respective control nodes NC0 to NC2 during reading. The non-selection gate voltage applied to the control node NC0 during reading may be used as it is, as the selection gate voltage Vgrm applied to the control node NC0 during reading. That is, during reading, the same read gate voltage Vgrm is applied to all the control nodes NC0. The selection gate voltages Vgps1 and Vgps2 applied to the control nodes NC1 and NC2 during writing may be used as they are, as the non-selection gate voltages applied to the control nodes NC1 and NC2 during reading. Even during writing, the same write gate voltage Vgpm may be applied to all the control nodes NC0.

When the address of the memory cell MC2 to be operated is specified during writing and reading, the bit line decoder 124 selects one or a plurality of bit lines BL corresponding to the address to apply the write drain voltage Vdp or the read drain voltage Vdr to the selected bit line(s) BL. A non-selection bit line voltage (for example, the reference voltage Vss) is applied to the non-selection bit line(s) BL.

When an address of each memory cell to be operated is specified during writing and read operation, the word line decoder 125 selects and non-selects the first word line WPL for the write operation and the second word line WRL for the read operation, corresponding to the address, depending on the type of operation. Specifically, during writing, the write gate voltage Vgps1 described above is applied to the selected one first word line WPL as the selection first word line voltage, the read gate voltage Vgrs1 described above is applied to the remaining (m−1) non-selected first word lines WPL as the non-selection first word line voltage, and the write gate voltage Vgps2 described above is applied to all the second word lines WRL as the non-selection second word line voltage. In addition, during reading, the read gate voltage Vgrs2 described above is applied to the one selected second word line WRL as the selection second word line voltage, the write gate voltage Vgps2 described above is applied to the remaining (m−1) non-selection second word lines WPL as the non-selection second word line voltage, and the read gate voltage Vgrs1 described above is applied to all the first word lines WRL as the non-selection first word line voltage.

When an address of memory cell to be written is specified during writing, the memory gate control circuit 126 selects one memory gate line MGL corresponding to the address, the write gate voltage Vgpm described above is applied to the selected memory gate line MGL as the selection memory gate line voltage, and the read gate voltage Vgrm described above is applied to the remaining (m−1) non-selection memory gate lines MGL as the non-selection memory gate line voltage. During writing, the write gate voltage Vgpm described above may be applied to all the memory gate lines MGL. In addition, the memory gate control circuit 126 applies the read gate voltage Vgrm described above to all the memory gate lines MGL during reading.

The sense amplifier circuit 127 detects the read current Idsr flowing from the selected bit line BL to the selected memory cell MC2 through the bit line decoder 124 to determine whether the memory transistor Qm of the selected memory cell MC 2 is in the semiconductor state or the resistor state. The sense amplifier circuit 127 includes the same number of sense amplifiers as the number of selected bit lines BL. The sense amplifier included in the sense amplifier circuit 127 may not be a current sense type sense amplifier which directly measures the read current Idsr, but the sense amplifier may be a voltage sense type sense amplifier that measures a node voltage on the current path of the read current Idsr such as the bit line BL or the bit line decoder 124 which changes according on the read current Idsr. Furthermore, the sense amplifier circuit 127 may have the circuit configuration in which the reference voltage lines VSL are provided independently for each column and the corresponding reference voltage line VSL of each column unit is connected, instead of the circuit configuration in which the bit line BL selected through the bit line decoder 124 is connected.

According to the circuit configuration shown in FIG. 6, during writing, the selected memory cell MC2 is in the first voltage application state, and the memory transistor Q1 in the memory cell MC2 transitions from the semiconductor state to the resistor state. In the memory cell MC2 of the non-selection row, the read gate voltage Vgrs1 (Vgrs1<Vth1 or Vgrs1<Vn3+Vth1), which is the non-selection first word line voltage, is applied to the gate of the first selection transistor Q1, the read gate voltage Vgps2 (Vgps2<Vth2 or Vgps2<Vn3+Vth2), which is an non-selection second word line voltage, is applied to the gate of the second selection transistor Q2, and both the first and second selection transistors Q1 and Q2 are brought into the OFF state, the write current Idsp does not flow through the memory transistor Q1, and the semiconductor state or resistor state of the memory transistor Q1 is maintained as it is. Furthermore, in the memory cell MC2 in the non-selection column, since reference voltage Vss same as the reference voltage line VSL is applied to the non-selection bit line BL, the write current Idsp does not flow through the memory transistor Q1 even in the selected row, resulting in the semiconductor state or resistor state of the memory transistor Q1 being maintained as it is.

Further, with the circuit configuration shown in FIG. 6, during reading, the selected memory cell MC2 is brought into the second voltage application state, and when the memory transistor Q1 in the memory cell MC2 is in the semiconductor state, the read current Idsr does not flow from the selection bit line BL to the memory cell MC2, and when the memory transistor Q1 is in the resistor state, the read current Idsr flows from the selected bit line BL to the memory cell MC2. In the memory cell MC2 of the non-selection row, the read gate voltage Vgrs1 (Vgrs1<Vth1 or Vgrs1<Vn3+Vth1), which is the non-selection first word line voltage, is applied to the gate of the first selection transistor Q1, the read gate voltage Vgps2 (Vgps2<Vth2 or Vgps2<Vn3+Vth2), which is an non-selection second word line voltage, is applied to the gate of the second selection transistor Q2, both the first and second selection transistors Q1 and Q2 are brought into the OFF state, and the read current Idsr does not flow from the selection bit line BL through the memory cell MC2 in the non-selection row regardless of the state of the memory transistor Q1. Furthermore, in the memory cell MC2 in the non-selection column, since reference voltage Vss same as the reference voltage line VSL is applied to the non-selection bit line BL, the read current Idsr does not flow through the memory transistor Q1 even in the selection row. In addition, in the present embodiment, even when some current flows temporarily through the non-selection bit line BL, since the non-selection bit line BL and the sense amplifier circuit 127 are separated from each other, the current flowing through the non-selection bit line BL is not measured by the sense amplifier circuit 127.

It should be noted that the detailed circuit configuration, device structure, and manufacturing method of the control circuit 122, the voltage generation circuit 123, the bit line decoder 124, the word line decoder 125, the memory gate control circuit 126, and the sense amplifier circuit 127 may be realized by using a known circuit configuration, and may be manufactured by using a known semiconductor manufacturing technique.

Since the memory cell MC 2 may be written at a low current/low voltage, the nonvolatile storage device 120 has low power consumption and is easily miniaturized. It goes without saying that a nonvolatile storage device may be formed by using the memory cell MC1 shown in FIG. 1(a) instead of the memory cell MC2.

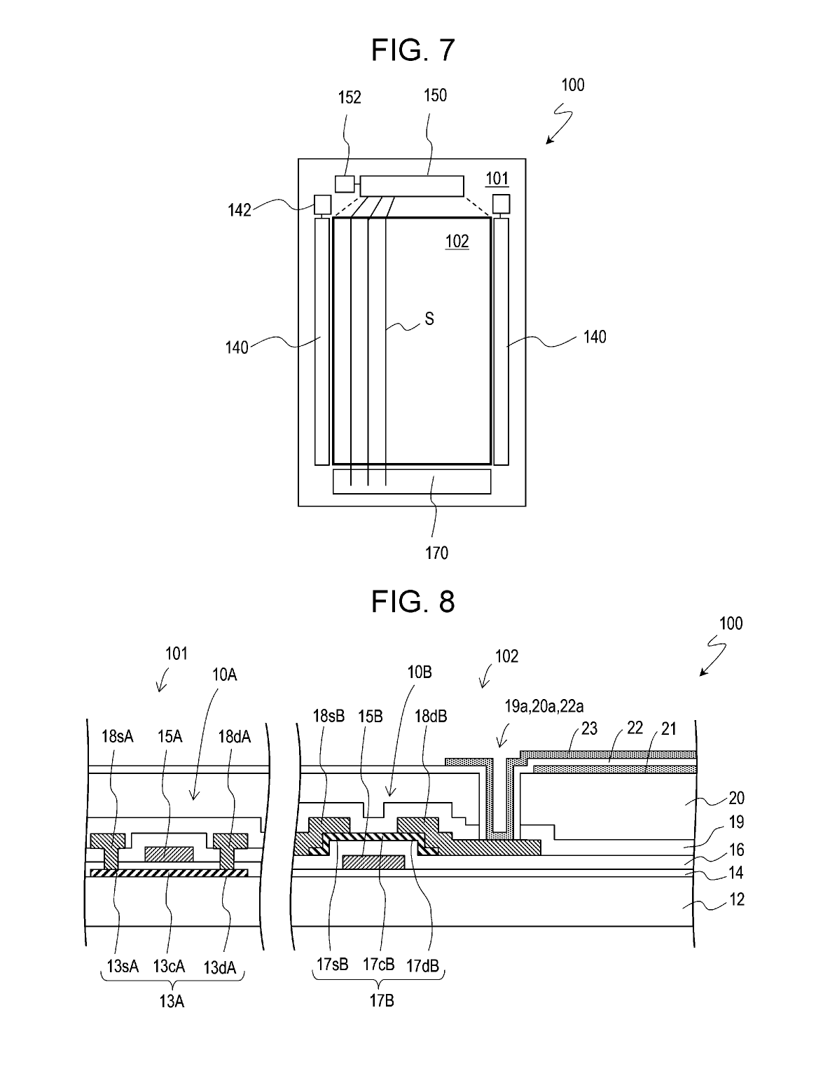

A semiconductor device according to an embodiment of the present invention is an active matrix substrate, for example. The active matrix substrate is used for a liquid crystal display panel or an organic EL display panel, for example. An active matrix substrate 100 used in a liquid crystal display panel will be described with reference to FIGS. 7 and 8.

For example, as disclosed in Japanese Unexamined Patent Application Publication No. 2010-3910, the active matrix substrate 100 uses an oxide semiconductor TFT as a pixel TFT and a crystalline silicon TFT as a circuit TFT. Since a TFT having an In—Ga—Zn—O-based semiconductor layer has high mobility (more than 20 times as compared with a-SiTFT) and low leak current (less than 1/100th of that of a-Si TFT), it is suitably used as a pixel TFT (TFT provided in a pixel). A crystalline silicon TFT having higher mobility than the oxide semiconductor TFT is used as the circuit TFT.

FIG. 7 shows a schematic plan view of the entire active matrix substrate 100 (hereinafter referred to as “TFT substrate 100”) according to an embodiment of the present invention. FIG. 8 is a schematic sectional view of the TFT substrate 100.

As shown in FIG. 7, the TFT substrate 100 includes a display region 102 including a plurality of pixels and a region (non-display region) other than the display region 102. The non-display region includes a drive circuit formation region 101 in which a drive circuit is provided. In the drive circuit formation region 101, a gate driver circuit 140, a source driver circuit 150, and an inspection circuit 170 are provided, for example. Nonvolatile storage devices 142 and 152 are connected to the gate driver circuit 140 and the source driver circuit 150, respectively. In the nonvolatile storage device 142, information of configuration parameters necessary for driving the gate driver circuit 140, such as redundancy repair information of the gate driver circuit 140, is stored, for example. In the nonvolatile storage device 152, information of configuration parameters necessary for driving the source driver circuit 150, such as redundancy repair information of the source driver circuit 150, is stored, for example. The nonvolatile storage devices 142 and 152 are nonvolatile storage devices according to the embodiments described above.

In the display region 102, a plurality of gate bus lines (not shown) extending in the row direction and a plurality of source bus lines S extending in the column direction are formed. Although not shown, each pixel is defined by a gate bus line and a source bus line S, for example. The gate bus lines are connected to the respective terminals of the gate driver circuit 140, and the source bus line S is connected to each terminal of the source driver circuit 150. It should be noted that only the gate driver circuit 140 may be monolithically formed on the TFT substrate 100 and the driver IC may be mounted as the source driver circuit 150.

As shown in FIG. 8, in the TFT substrate 100, a first TFT 10A is formed in the drive circuit formation region 101 as a circuit TFT, and a second TFT 10B is formed as a pixel TFT in each pixel of the display region 102.

The TFT substrate 100 includes a substrate 12 and the first TFT 10A and the second TFT 10B formed on the substrate 12. The substrate 12 is a glass substrate and a base film (not shown) may be formed on the substrate 12, for example. When the base film is formed, circuit elements such as the first TFT 10A and the second TFT 10B are formed on the base film. The base film is not particularly limited, but is an inorganic insulating film, and is a laminated film having a silicon nitride (SiNx) film, a silicon oxide (SiOx) film, or a silicon nitride film as a lower layer and a silicon oxide film as an upper layer, for example.

The first TFT 10A includes an active region mainly including crystalline silicon. The second TFT 10B includes an active region mainly including an oxide semiconductor. The first TFT 10A and the second TFT 10B are integrally formed on the substrate 12.

The nonvolatile storage devices 142 and 152 include the memory transistor 10M and the selection transistor 10S shown in FIG. 2. The memory transistor 10M having the oxide semiconductor layer 17M is formed by the same process as the second TFT 10B as the pixel TFT having the oxide semiconductor layer 17B. In addition, the selection transistor 10S having the crystalline silicon layer 13S is formed by the same process as the first TFT 10A as the circuit TFT having the crystalline silicon layer 13A. That is, the oxide semiconductor layer 17M and the oxide semiconductor layer 17B are formed of the same oxide semiconductor film, and the crystalline silicon layer 13S and the crystalline silicon layer 13A are formed of the same crystalline silicon film. In addition, the first insulating layer 14, the second insulating layer 16, and the third insulating layer 19 may be common to the memory transistor 10M and the selection transistor 10S and the first TFT 10A and the second TFT 10B.

Therefore, even when the nonvolatile storage devices 142 and 152 are provided on the active matrix substrate including the first TFT 10A having the crystalline silicon layer 13A and the second TFT 10B having the oxide semiconductor layer 17B, it is possible to suppress an increase in the number of manufacturing steps.

Hereinafter, the structures of the first TFT 10A and the second TFT 10B of the active matrix substrate 100 will be described with reference to FIG. 8.

The first TFT 10A includes a crystalline silicon layer (for example, a low temperature polysilicon layer) 13A formed on the substrate 12, a first insulating layer 14 covering the crystalline silicon layer 13A, and a gate electrode 15A provided on the first insulating layer 14. A portion of the first insulating layer 14, which is located between the crystalline silicon layer 13A and the gate electrode 15A, serves as a gate insulating film of the first TFT 10A. The crystalline silicon layer 13A includes a region (active region) 13cA where a channel is formed and a source region 13sA and a drain region 13dA located on both sides of the active region, respectively. In this example, the portion of the crystalline silicon layer 13A, which is overlapping with the gate electrode 15A through the first insulating layer 14 interposed therebetween is an active region 13cA. The first TFT 10A also includes a source electrode 18sA and a drain electrode 18dA connected to the source region 13sA and the drain region 13dA, respectively. The source electrode 18sA and the drain electrode 18dA may be provided on an interlayer insulating film (here, the second insulating layer 16) covering the gate electrode 15A and the crystalline silicon layer 13A, and may be formed within a contact hole formed on the interlayer insulating film to be connected to the crystalline silicon layer 13A. As described above, the first TFT 10A is a top gate type TFT.

The second TFT 10B is a bottom gate type TFT and includes a gate electrode 15 B, a second insulating layer 16 covering the gate electrode 15 B, and an oxide semiconductor layer 17B disposed on the second insulating layer 16. Here, the gate electrode 15B is provided on the first insulating layer 14 formed on the substrate 12. The first insulating layer 14, which is the gate insulating film of the first TFT 10A, is extended to the region where the second TFT 10B is formed. The gate electrode 15B is formed of the same conductive film as the gate electrode 15A of the first TFT 10A.

A portion of the second insulating layer 16, which is located between the gate electrode 15B and the oxide semiconductor layer 17B, serves as a gate insulating film of the second TFT 10B. The second insulating layer 16 may have a two-layer structure of a hydrogen-donor lower layer (for example, a silicon nitride (SiNx) layer), for example, and an oxygen-donor upper layer (for example, a silicon oxide (SiOx) layer).

The oxide semiconductor layer 17B includes a region (active region) 17cB in which a channel is formed and a source contact region 17sB and a drain contact region 17dB which are located on both sides of the active region, respectively. In this example, a portion of the oxide semiconductor layer 17B, which is overlapped with the gate electrode 15B through the second insulating layer 16 interposed therebetween, is an active region 17cB. In addition, the second TFT 10B further includes a source electrode 18sB and a drain electrode 18dB connected to the source contact region 17sB and the drain contact region 17dB, respectively.

The TFTs 10A and 10B are covered with the third insulating layer 19 and the fourth insulating layer 20. On the fourth insulating layer 20, a common electrode 21, a fifth insulating layer 22, and a pixel electrode 23 are formed in this order. The pixel electrode 23 includes a slit (not shown). A plurality of slits may be provided. The common electrode 21 and the pixel electrode 23 are formed of a transparent conductive layer. As the transparent conductive layer, indium tin oxide (ITO), indium zinc oxide (IZO, “IZO” is registered trademark), zinc oxide (ZnO) or the like may be formed, for example.

The pixel electrode 23 is connected to the drain electrode 18dB in openings 19a, 20a, and 22a formed in the third insulating layer 19, the fourth insulating layer 20, and the fifth insulating layer 22. The common electrode 21 is provided for a plurality of pixels in common, and is connected to a common wiring and/or a common electrode terminal (not shown), and is supplied with a common voltage (Vcom).

In the above embodiment, a channel etch type TFT is exemplified as the oxide semiconductor TFT, but an etch stop type TFT may also be used. In the channel etch type TFT, for example, as shown in FIG. 8, the etch stop layer is not formed on the channel region, and the lower surface of the end portion on the channel side of the source and drain electrode is disposed to be in contact with the upper surface of the oxide semiconductor layer. The channel etch type TFT is formed by forming a conductive film for a source and a drain electrode on an oxide semiconductor layer and separating the source and drain, for example. In the source and drain separation step, the surface portion of the channel region may be etched, in some cases.

Meanwhile, in the TFT (etch stop type TFT) in which the etch stop layer is formed on the channel region, the lower surface of the end portion on the channel side of the source and drain electrode is located on the etch stop layer, for example. The etch stop type TFT is formed by forming a conductive film for a source and a drain electrode on an oxide semiconductor layer and the etch stop layer and separating the source and drain, and then forming an etch stop layer that covers a portion to be a channel region in the oxide semiconductor layer, for example. Etch stop type TFTs are described in PTLs 1 and 2, for example.

### INDUSTRIAL APPLICABILITY

The present invention is widely used for a semiconductor device having a memory transistor.

### REFERENCE SIGNS LIST

10A, 10B TFT
10M Memory transistor
10S, 10S1, 10S2 Selection transistor
10S1 First selection transistor
12 Substrate
13A, 13S Crystalline silicon layer
13cA, 13cS Active region
13dA, 13dS Drain region
13sA, 13sS Source region
14 First insulating layer
15A, 15B, 15M, 15S Gate electrode
16 Second insulating layer
17B, 17M Oxide semiconductor layer
17cB, 17cM Channel region (active region)
17dB, 17dM Drain contact region
17sB, 17sM Source contact region
18dA, 18dB, 18dM, 18dS Drain electrode
18sA, 18sB, 18sM, 18sS Source electrode
19 Third insulating layer
19a Opening
20 Fourth insulating layer
20a Opening
21 Common electrode
22 Fifth insulating layer
22a Opening
23 Pixel electrode
26 Memory gate control circuit
100 Active matrix substrate (TFT substrate)
100 TFT substrate
101 Drive circuit formation region
102 Display region
120 Nonvolatile storage device
121 Memory cell array
122 Control circuit
123 Voltage generation circuit
124 Bit line decoder
125 Word line decoder
126 Memory gate control circuit
127 Sense amplifier circuit
140 Gate driver circuit
142 Nonvolatile storage device
150 Source driver circuit
152 Nonvolatile storage device
170 Inspection circuit
BL Bit line
BL1 Bit line
MC1 and MC2 Memory cell
MGL, MGL1 Memory gate line
N0, N1 and N2, N3 Node
NC0, NC1, NC2 Control node
Q1, Q2 Selection transistor
Qm Memory transistor
S Source bus line
WPL Word line

1: A semiconductor device comprising a plurality of memory cells,
wherein each of the plurality of memory cells includes
a memory transistor having an oxide semiconductor layer as an active layer, and
a first selection transistor having a crystalline silicon layer as the active layer and connected to the memory transistor in series.

2: The semiconductor device according to claim 1,
wherein each of the plurality of memory cells further includes a second selection transistor having a crystalline silicon layer as an active layer and connected to the memory transistor in series.

3: The semiconductor device according to claim 1,
wherein the transistors that are included in each of the plurality of memory cells are only the memory transistor and the first selection transistor.

4: The semiconductor device according to claim 1,
wherein the semiconductor device is an active matrix substrate,
the semiconductor device includes
a display region including a plurality of pixel electrodes and pixel transistors each of which is electrically connected to the corresponding pixel electrode of the plurality of pixel electrodes, and
a peripheral region having a plurality of circuits arranged in a region other than the display region,
the plurality of circuits include a memory circuit having the plurality of memory cells, and
an active layer of the pixel transistor includes a semiconductor layer formed of the same oxide semiconductor film as that of the oxide semiconductor layer of the memory transistor.

5: The semiconductor device according to claim 1,
wherein the oxide semiconductor layer includes an In—Ga—Zn—O-based semiconductor.

6: The semiconductor device according to claim 1,
wherein the oxide semiconductor layer includes a crystalline In—Ga—Zn—O-based semiconductor.

7: The semiconductor device according to claim 1,
wherein the active layer of the memory transistor has a stacked structure.

8: The semiconductor device according to claim 1,
wherein the memory transistor is a channel etch type.
